(19) United States
(12) Patent Application Publication
(10) Pub. No.: US 2005/0217460 A1
(43) Pub. Date: Oct. 6, 2005

(54) Apparatus and method for enhanced musical performance reproduction using a digital radio

(76) Inventor: Robert G. DeMoor, Sugar Land, TX (US)

Correspondence Address: TEXAS INSTRUMENTS INCORPORATED, P O BOX 655474, M/S 3999, DALLAS, TX, 75265, US

(21) Appl. No.: 10/815,136

(22) Filed: Mar. 31, 2004

(51) Int. Cl. G11C 5/00; G10H 7/00; G10H 5/00; G10H 1/40

(52) U.S. Cl. 84/603

(57) ABSTRACT

In order to enhance the performance of audio presentation of a digital radio, the digital radio presentation is analyzed to extract the parameters of at least one selected instruments. The selected instrument parameters, for example, pitch, intensity, etc., are then reformatted in the form of control signals. The control signals are applied to an automatic (electrically driven) version of the selected instrument. The performance of the selected automatic instrument is played in synchronism with the audio presentation. The present of an actual instrument playing in synchronism with the audio presentation from the speakers driven by the digital radio provides an augmented listening experience.

### FIELD OF THE INVENTION

This invention relates generally to digital radios and, more particularly, to the use of the digital radio to enhance the reproduction of a musical performance.

### BACKGROUND OF THE INVENTION

The digital radio is becoming widely available. As the technology has increased the sampling rate and the processing capability of the digital radio, the performance reproduction has improved. Similarly, improvements in the speaker systems have added an immediacy to the listening experience of a musical performance that has not been available previously. In addition, the digital radio has flexibility and capabilities that have not as yet been exploited.

At the present time, a multiplicity of formats for signal transmission are in use for digital radios. The common factor of these formats is the inclusion, in the broadcast band, of at least one digital-encoded channel. Referring to FIG. 1, a block diagram of a digital radio 10 capable of receiving and processing the broadcast band transmission, according to the prior art, is shown. The digital radio 10 includes an antenna unit 5. The antenna unit 5 can be a part of the digital radio 10 or can be coupled to the digital radio 10 by a conducting element. The signals picked up by the antenna 5 are applied to the receiver unit/down-converter unit 101. The output signals of the receiver unit/down-converter unit 101 are modulated signals having an intermediate frequency. The receiver unit/down-converter unit 101 applies the intermediate frequency signals to analog-to-digital converter unit 102. The analog-to-digital converter 102 converts the digitally encoded signal carriers and the analog-encoded signal carriers to digital serial data. The output signals from the analog-to-digital converter 102 are applied to the demodulator unit/processor unit 103. The demodulator unit/processor unit 103 demodulates and decodes both the analog and digitally transmitted signal content. The analog and digital signal channel signals are applied to the demodulator unit/processing unit 103 together, but are demodulated and processed separately in the unit 103. The demodulator unit/processing unit 103 exchanges program and data signals with the memory unit 104. The processing unit 103, in response to a user input and the program stored in memory unit 104, processes the signals received from the analog-to-digital converter unit 102. For example, a decompression algorithm can be applied to the received signals. The processed signals from the demodulator unit/processing unit 103 are applied to digital to analog converter unit 105. The output signals from the digital-to-analog converter unit 105 are applied through amplifying units 109 through 110 to speaker units 107 through 108, respectively.

As will be clear to those skilled in the art, the foregoing description is meant to be illustrative rather than comprehensive. At the present time, a standardized format for the digital radio broadcast band transmission has not been adopted.

Even with the advanced technology such as high sampling rates, the reproduction of an audio performance, such as a musical performance, lacks the immediacy and the nuances that are enjoyed by the more sophisticated listener. This problem is principally the result of limitations of the speaker systems.

In a separate field, automatic musical instruments are being developed and improved. By way of specific example, the modern version of the player piano includes a complete piano. However, instead of the pneumatic apparatus of an earlier day, electrically-driven solenoids, controlled by electric signals, can be used to create an audio performance replica that is substantially equivalent to a live performance.

A need has therefore been felt for apparatus and an associated method having the feature that an audio performance transmitted by radio broadcast bands can be enhanced. It is another feature of the apparatus and associated method to enhance the audio performance provided by a digital radio by adding an automatic instrument to the performance. It is still another feature of the apparatus and associated method to provide an automatic instrument controlled by the signals received and processed a digital radio. It is a further feature of the apparatus and associated method to improve the quality of a performance reproduction by using at least portion of a transmitted radio band signal to drive an automatic instrument.

### SUMMARY OF THE INVENTION

The aforementioned and other features are accomplished, according to the present invention, by providing the processing unit of a digital radio with the ability to identify the parameters associated with at least one instrument in a performance. These parameters are then used to control the operation of an automatic musical instrument. The automatic musical instrument is then played either alone or as part of a performance being provided by the digital radio. The presence of the automatic instrument provides the audience with nuances that are typically lost in the detection, modulation, demodulation, and presentation by a speaker system of the performance.

Other features and advantages of the present invention will be more clearly understood upon reading of the following description and the accompanying drawings and claims.

### BRIEF DESCRIPTION OF THE DRAWINGS

FIG. 1 is block diagram of a digital radio according to the prior art.

FIG. 2 is a block diagram of a digital radio according to the present invention along with an associated automatic instrument.

FIG. 3 illustrated one embodiment of the process for improving the reproduction of a performance according to the present invention.

### DESCRIPTION OF THE PREFERRED EMBODIMENT

1. Detailed Description of the Drawings

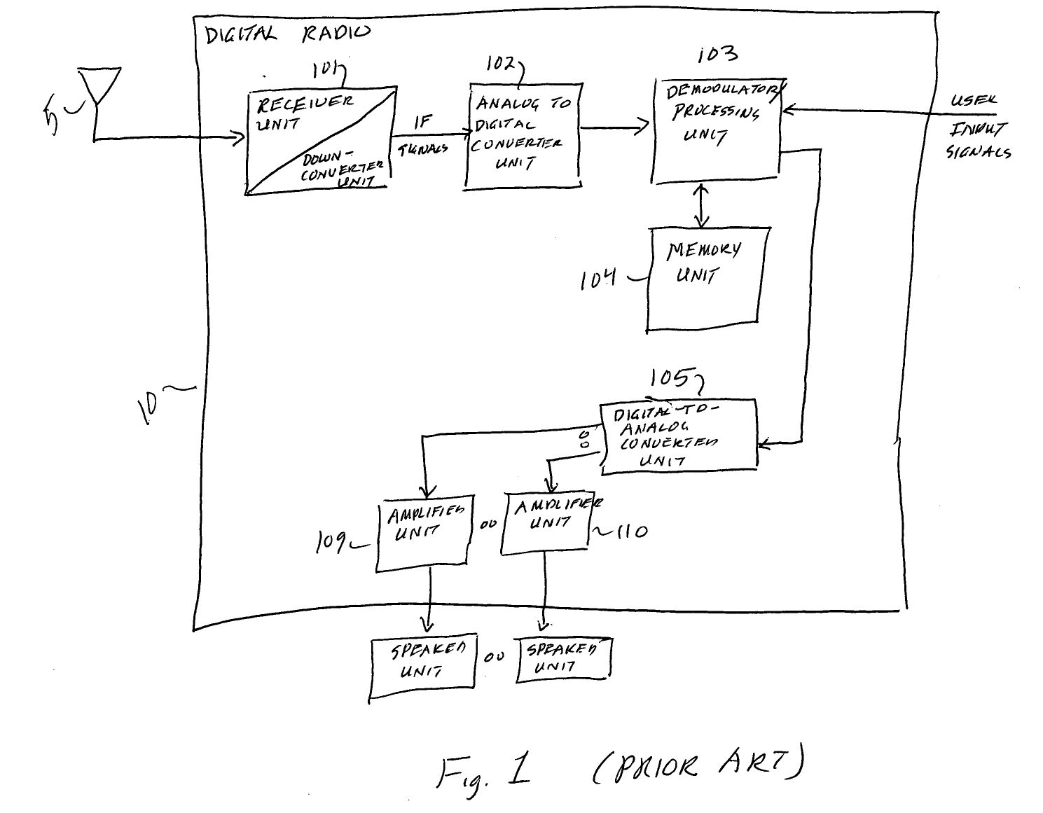

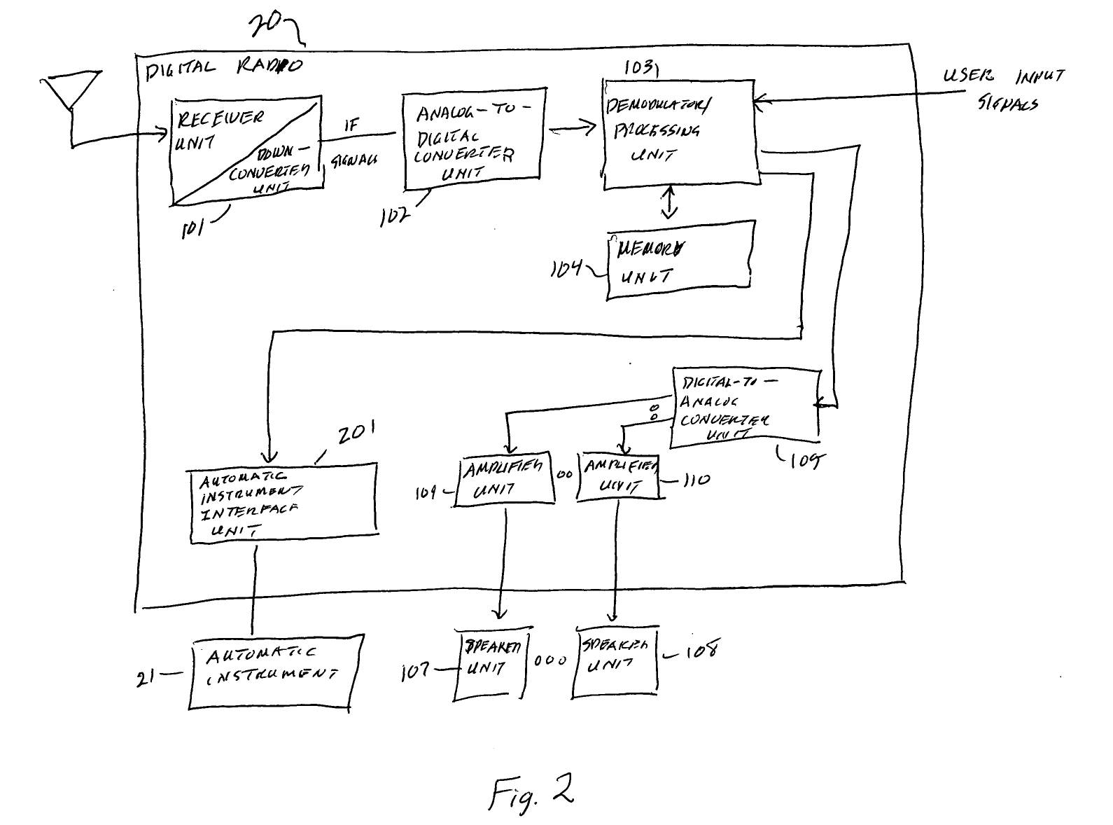

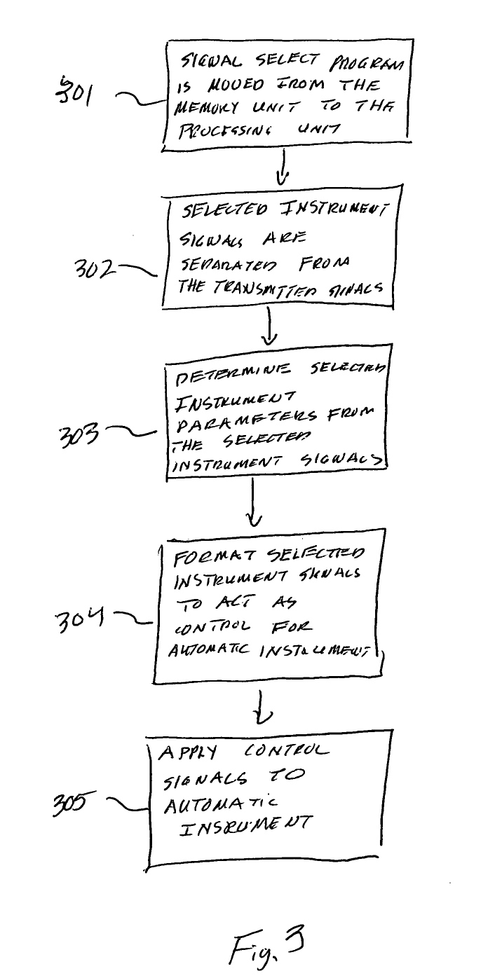

Referring to FIG. 2, the block diagram of the digital radio 20 and an automatic musical instrument 21, according to the present invention, is shown. The digital radio 20 includes the components that were present in the prior art digital radio 10 shown in FIG. 1. The added component is an automatic instrument interface unit 201. The signals from the processing unit 102 that can be used to control the automatic instrument 21 are reformatted in the interface unit 201 in a manner to provide control signals that determine the pitch, the loudness, and other features of the output signal of the automatic instrument 21. The principal innovative activity is actually performed in the processing unit 102 in response to programming stored in the memory unit 104 and in response to user input signals. This activity is described in FIG. 3.

Referring now to FIG. 3, the procedure performed by the processing unit 103 in the implementation of the present invention is described. In response to user input signals, a signal select program is transferred from the memory unit 104 to the demodulator/processing unit 103 in step 301. In step 302, the signal select program is used to separate the signals in the received signal band associated with a selected instrument. The selected instrument has an embodiment as an automatic instrument. After the signals associated with the selected instrument are separated from the other transmitted signals, the selected signals are used to determine the parameters of the selected signals, such as pitch etc. in step 303. With the parameters of the selected signals associated with the automatic instrument determined, the signals are reformatted in a form of control signals such that, when applied to the automatic instrument the resulting sound replicates the transmitted sound of the selected signals in step 304. In step 305, the control signals are applied to the automatic instrument in synchronism with the transmitted signals from which the selected signals were extracted. Note, in FIG. 3, the selected signals are reformatted in an interface unit 201 included in the digital radio 20. As will also be clear, this interface unit could actually be external to the digital radio 20 without departing from the present invention. Then at least a portion of the reformatting of the selected signals can be performed by the demodulator/processing unit.

2. Operation of the Preferred Embodiment

The present invention, by adding at least one actual instrument to an audio presentation provides for reverberations, overtones and other features of an actual musical instrument that can be lost in detection, transmission, and the reproduction of an audio presentation. Then at least one selected instrument is an automatic instrument driven by control signals derived from the audio presentation. Thus, the subtle audio shadings that are normally present in live audio presentation, but not in the reproduction of the audio presentation, can be provided to the listener of the reproduction.

In the preferred embodiment, a selected instrument is selected from a plurality of instruments in a performance. The parameters that are used to control the automatic instrument include intensity pitch, attack, decay, etc. These parameters can be acquired by selective filtering of the performance signals. However, control signals for the automatic instrument can also be provided in one of the digital carrier signals of the broadcast channel. In case of a performance involving only a single instrument, only the filtering necessary is to determine the performance parameters for the automatic instrument and not the filtering necessary to separate the signals from the automatic instrument from the signals from other instruments.

It will also be clear that more than one automatic instrument can be used in an audio presentation.

While the invention has been described with respect to the embodiments set forth above, the invention is not necessarily limited to these embodiments. Accordingly, other embodiment variations, and improvements not described herein, are not necessarily excluded from the scope of the invention, the scope of the invention being defined by the following claims.

1. An apparatus for reproducing an audio presentation provided by transmitted signals, the apparatus comprising:
a digital radio, the digital radio programmed to separate signals of a selected instrument from transmitted signals;
an automatic selected instrument adapted to be activated by electrical control signals; and
an interface unit for reformatting the separate signals into the control signals.

2. The apparatus as recited in claim 1 wherein the activation of the automatic selected instrument is synchronized with the separate signals.

3. The apparatus as recited in claim 1 wherein the separate signals are transmitted in the digital carriers of the digital radio transmission.

4. The apparatus as recited in claim 1 wherein the separate signals are transmitted as a program service component of the transmitted digital radio transmission.

5. The apparatus as recited in claim 1 wherein the digital radio programmed to separate signals of a second selected instrument from transmitted signals; the apparatus further comprising:
a second automatic selected instrument adapted to be activated by electrical control signals; and
an interface unit for reformatting the separate signals of the second selected instrument into the control signals for the second automatic selected instruments.

6. A method for reproduction of a transmitted audio presentation, the method comprising:
playing the transmitted audio presentation over a speaker system;
separating the signals for a selected instrument from the audio;
generating control signals capable of driving a selected automatic instrument; and
driving the selected automatic instrument in synchronism with the audio presentation.

7. The method as recited in claim 6 further comprising driving the selected automatic instrument in synchronism if the signals separated from the audio presentation.

8. An apparatus for reproducing an audio presentation, the apparatus comprising:
a processing unit receiving an audio presentation, the processing unit separating selected instrument signals from the audio presentation;
at least one speaker responsive to output signals from the processing unit for reproducing the audio presentation;
an interface unit for reformatting the separated selected instrument signals from the processing unit into control signals; and
an automatic selected musical instrument responsive to control signals from interface unit for reproducing the audio presentation of the selected instrument.

9. The apparatus as recited in claim 8 wherein the processing unit is included in a digital radio.

10. The apparatus as recited in claim 8 wherein the output signal from the processing unit includes the separated selected signals.

11. The apparatus as recited in claim 8 wherein the output signal from the processing unit does not include the separated selected signals.

12. The apparatus as recited in claim 8 wherein the processing unit separates second selected instrument signals from the audio presentation;
a second interface unit for reformatting the separated second selected instrument signals from the processing unit into second control signals; and
a second automatic selected musical instrument responsive to second control signals from interface unit for reproducing the audio presentation of the second selected instrument.

13. The apparatus as recited in claim 8 wherein the audio presentation from the speakers is synchronized with the audio presentation of the automatic selected musical instruments.
